(19) United States
(12) Patent Application Publication
(10) Pub. No.: US 2026/0005101 A1
(43) Pub. Date: Jan. 1, 2026

(54) HEAT DISSIPATION MEMBER, HEATING COMPONENT, ELECTRONIC ASSEMBLY AND DEVICE

(71) Applicant: Delta Electronics (Shanghai) Co., Ltd., Shanghai (CN)

(72) Inventor: Jie ZHAO, Shanghai (CN)

(21) Appl. No.: 19/250,101

(22) Filed: Jun. 26, 2025

(30) Foreign Application Priority Data
Jun. 28, 2024 (CN) 202410866078.5

(51) Int. Cl. H01L 23/427; H01L 23/367

(52) U.S. Cl. CPC H01L 23/427; H01L 23/3677

(57) ABSTRACT

Embodiments of the present application provide a heat dissipation member, a heating component, an electronic assembly and a device, and belong to the technical field of heat dissipation. The heat dissipation member is configured for the heating component, and includes a first surface and a second surface which are oppositely disposed along a gravity direction, where the first surface is located above the second surface; an extending direction of at least a part of the second surface is different from a horizontal direction; the first surface is located below the heating component, and the at least a part of the second surface is disposed to be immersed in phase-change cooling liquid.

### CROSS-REFERENCE TO RELATED APPLICATIONS

This application claims priority to Chinese Patent Application No. 202410866078.5, filed on Jun. 28, 2024, which is hereby incorporated by reference in its entirety.

### TECHNICAL FIELD

The present application relates to the technical field of heat dissipation, and specifically relates to a heat dissipation member, a heating component, an electronic assembly and a device.

### BACKGROUND

With the progressive development of electronic assemblies in a direction of miniaturization and high power density, people have higher and higher requirements for heat dissipation of the electronic assemblies. Phase-change-immersion liquid cooling technology has attracted attention due to its advantages, such as ultra-high heat dissipation efficiency, uniform temperature, low noise and pollution-free, and high integration or the like.

In the related art, a phase-change-immersion liquid heat-dissipation module may include a housing, phase-change cooling liquid, a condensing coil and an electronic assembly, where the housing has an accommodating cavity, and the phase-change cooling liquid, the condensing coil and the electronic assembly are all located in the accommodating cavity. The phase-change cooling liquid is located at a bottom of the accommodating cavity, the electronic assembly is immersed in the cooling liquid, and the condensing coil is located at a top of the accommodating cavity and has a spacing from the cooling liquid. The electronic assembly may include a circuit board and a heating component. Through phase-change-and-vaporization of the cooling liquid, heat of the heating component is taken away, and the vaporized cooling liquid is in a vapor state. After rising and contacting with the condensing coil for heat exchange and being cooled, the vapor is liquefied and drops down. In this way, the circulation is repeated to achieve cooling of the heating component.

Generally, in the phase-change-immersion liquid heat-dissipation module, a phase-change process of the cooling liquid is mainly nucleate boiling state and transition boiling state. When the temperature of the heat dissipation member/heating component exceeds the saturation temperature of the phase-change cooling liquid and reaches a certain value, bubbles are continuously generated by the liquid on a surface layer of a heating surface at a vaporization core of the heating surface. The bubbles absorb heat and grow up, separate from the heating surface, and then float upwards. The liquid is violently disturbed and rolled due to the separation and rising movement of the bubbles and the driven of internal temperature difference of the liquid, thereby forming turbulence. Therefore, the speed of the bubbles of separating from the heating surface has a great influence on the boiling-and-heat-transfer effect. Once the bubbles separate from the heating surface, they enter a mainly boiling region of the liquid and are carried away by the turbulence. In a floating process of the bubbles in the liquid, if the cooling liquid does not reach its saturation temperature, they float to the liquid and break and disappear; and if the cooling liquid reaches its saturation temperature, they float to a liquid surface and break, and the cooling liquid is vaporized into vapor. After rising and contacting with the condensing coil for heat exchange and being cooled, the vapor is liquefied and drops down. In this way, the circulation is repeated to achieve cooling of the heating component.

However, when the heating component is located at a bottom of the circuit board, a lower surface of the heating component or the heat dissipation member is a horizontal surface, which cannot generate a force to make the bubble separate. The bubble which is generated at the vaporization core, continuously grows after absorbing heat, and when growing to a certain diameter (that is, a separating diameter of the bubble), it slides away along the heating surface. In this case, the speed of the bubble separating from the heating surface is very slow, and it cannot separate from the lower surface of the heating component or the heat dissipation member in time, so that a plurality of bubbles generated by boiling are gathered and combined into a large flat bubble to cover the lower surface, which hinders direct heat exchange between the heating surface and the cooling liquid, causes that the heat transfer coefficient is decreased, and affects the heat dissipation effect. Therefore, it is necessary to improve the heat dissipation structure of the heating component or the heat dissipation member.

### SUMMARY

In view of the above at least one technical problem, embodiments of the present application provide a heat dissipation member, a heating component, an electronic assembly and a device, which can improve heat dissipation effect of phase-change cooling liquid on the heat dissipation member, the heating component and the electronic assembly.

The embodiments of the present application provide the following technical solutions.

A first aspect of an embodiment of the present application provides a heat dissipation member, configured for a heating component, including a first surface and a second surface which are oppositely disposed along a gravity direction, where the first surface is located above the second surface; an extending direction of at least a part of the second surface is different from a horizontal direction; the first surface is located below the heating component, and the at least a part of the second surface is disposed to be immersed in phase-change cooling liquid.

The heat dissipation member provided by the embodiment of the present application, is configured for the heating component. The heat dissipation member includes a first surface and a second surface which are oppositely disposed along a gravity direction, where the first surface is located above the second surface; an extending direction of at least a part of the second surface is different from a horizontal direction; the first surface is located below the heating component, and the at least a part of the second surface is disposed to be immersed in phase-change cooling liquid. In this way, by setting the extending direction of the at least a part of the second surface, which is immersed in the phase-change cooling liquid, to be different from the horizontal direction, when a bubble is generated at a vaporization core of the at least a part of the second surface, a force enabling the bubble to separate can be generated, so that it is easily for the bubble to separate from the at least a part of the second surface, and the separating speed of the bubble is faster. After separating, the bubble enters the main body of the boiling cooling liquid and is taken away by turbulence, thereby alleviating a hindrance of a large bubble in heat exchange between the second surface and the cooling liquid, improving the boiling-and-heat-transfer coefficient, and improving the heat dissipation effect of the phase-change cooling liquid on the heat dissipation member.

In a possible implementation, the second surface includes at least one of an inclined plane which is obliquely intersected with the first surface and a curved surface, the inclined plane or the curved surface forms a first projection on the first surface along a direction perpendicular to the first surface, and a length between two points in the first projection is greater than or equal to 0.3 mm.

In a possible implementation, the second surface further includes a plane parallel to the first surface.

In a possible implementation, the second surface further includes the inclined plane, and an included angle between the inclined plane and the horizontal direction is greater than or equal to 10 degrees.

In a possible implementation, the second surface includes the curved surface, and curvature of the curved surface is greater than or equal to 0.00264.

In a possible implementation, the first surface is parallel to the horizontal direction, and flatness of the first surface is less than or equal to 0.1 mm.

In a possible implementation, roughness of the second surface is greater than or equal to 0.01 mm and less than or equal to 0.3 mm.

In a possible implementation, thermal conductivity of the heat dissipation member is greater than or equal to 20 W/(m*k).

In a possible implementation, the second surface includes a plurality of sub-surfaces, each of the plurality of sub-surfaces is in form of inclined plane or the curved surface, and extending directions of two adjacent sub-surfaces are different.

A second aspect of an embodiment of the present application provides a heating component. The heating component generates heat during an operation, and includes a first surface and a second surface which are oppositely disposed along a gravity direction, where the first surface is located above the second surface; at least a part of the second surface is an inclined plane which is obliquely intersected with a horizontal direction and/or a curved surface, and at least a part of the second surface is disposed to be immersed in phase-change cooling liquid.

For the heating component provided by the embodiment of the present application, by setting the extending direction of the at least a part of the second surface, which is immersed in the phase-change cooling liquid, to be different from the horizontal direction, when a bubble is generated at a vaporization core of the at least a part of the second surface, a force enabling the bubble to separate can be generated, so that it is easily for the bubble to separate from the at least a part of the second surface, and the separating speed of the bubble is faster. After separating, the bubble enters the main body of the boiling cooling liquid and is taken away by turbulence, thereby alleviating a hindrance of a large bubble in heat exchange between the heating surface and the liquid working medium, improving the boiling-and-heat-transfer coefficient, and improving the heat dissipation effect of the phase-change cooling liquid on the heating component.

A third aspect of an embodiment of the present application provides an electronic assembly, including the heat dissipation member in the above first aspect and a heating component. Where the heating component generates heat during an operation. The heating component is located on the first surface of the heat dissipation member.

The electronic assembly provided by the embodiment of the present application includes the heat dissipation member. The heat dissipation member includes a first surface and a second surface which are oppositely disposed along a gravity direction, where the first surface is located above the second surface; an extending direction of at least a part of the second surface is different from a horizontal direction; the first surface is located below the heating component, and the at least a part of the second surface is disposed to be immersed in phase-change cooling liquid. In this way, by setting the extending direction of the at least a part of the second surface, which is immersed in the phase-change cooling liquid, to be different from the horizontal direction, when a bubble is generated at a vaporization core of the at least a part of the second surface, a force enabling the bubble to separate can be generated, so that it is easily for the bubble to separate from the at least a part of the second surface, and the separating speed of the bubble is faster. After separating, the bubble enters the main body of the boiling cooling liquid and is taken away by turbulence, thereby alleviating a hindrance of a large bubble in heat exchange between the second surface and the liquid working medium, improving the boiling-and-heat-transfer coefficient, and improving the heat dissipation effect of the phase-change cooling liquid on the heat dissipation member.

In a possible implementation, a surface of the heating component, which is away from the first surface, is adjacent to a surface of a circuit board, and a thickness direction of the circuit board is parallel to a gravity direction.

In a possible implementation, the electronic assembly further includes an auxiliary heat-dissipation member, where the auxiliary heat-dissipation member is located between the first surface and the circuit board, and is annularly disposed around periphery of the heating component; the auxiliary heat-dissipation member is in contact with the heating component, or there is a spacing between the auxiliary heat-dissipation member and the heating component.

In a possible implementation, the heating component is an electronic component or a power supply module.

In a possible implementation, the auxiliary heat-dissipation member, the heat dissipation member and the heating component are packaged in whole.

In a possible implementation, the electronic assembly further includes a first auxiliary heat-dissipation member, a second auxiliary heat-dissipation member and a circuit board, where the heating component includes a first heating component and a second heating component, a thickness direction of the circuit board is parallel to a horizontal direction, and the first heating component and the second heating component are respectively located at two sides of the circuit board in the thickness direction; the first auxiliary heat-dissipation member is located at a side of the first heating component facing away from the circuit board, a part of the second auxiliary heat-dissipation member is located at a side of the circuit board facing away from the heat dissipation member, and the other part of the second auxiliary heat-dissipation member is located at a side of the second heating component facing away from the circuit board and is connected with the heat dissipation member.

A fourth aspect of an embodiment of the present application provides a device, including: a phase-change cooling assembly and the electronic assembly in the above third aspect, where the phase-change cooling assembly includes a housing and phase-change cooling liquid, the housing has an accommodating cavity, the phase-change cooling liquid is located in the accommodating cavity, and at least a part of the second surface of the heat dissipation member of the electronic assembly is immersed in the phase-change cooling liquid.

The device provided by the embodiment of the present application includes the heat dissipation member. The heat dissipation member includes a first surface and a second surface which are oppositely disposed along a gravity direction, where the first surface is located above the second surface; an extending direction of at least a part of the second surface is different from a horizontal direction; the first surface is located below the heating component, and the at least a part of the second surface is disposed to be immersed in phase-change cooling liquid. In this way, by setting the extending direction of the at least a part of the second surface, which is immersed in the phase-change cooling liquid, to be different from the horizontal direction, when a bubble is generated at a vaporization core of the at least a part of the second surface, a force enabling the bubble to separate can be generated, so that it is easily for the bubble to separate from the at least a part of the second surface, and the separating speed of the bubble is faster. After separating, the bubble enters the main body of the boiling cooling liquid and is taken away by turbulence, thereby alleviating a hindrance of a large bubble in heat exchange between the heating surface and the liquid working medium, improving the boiling-and-heat-transfer coefficient, and improving the heat dissipation effect of the phase-change cooling liquid on the heat dissipation member, the heating component and the electronic assembly, so as to avoid damaging the heating component and improve the heat dissipation effect of the device.

In a possible implementation, a boiling point of the phase-change cooling liquid is greater than or equal to 40° C. and less than or equal to 70° C.

In a possible implementation, the phase-change cooling liquid is dielectric insulation liquid.

The structure of the present application, as well as its other inventive objectives and beneficial effects, would be more apparent by combining the accompanying drawings and the description of embodiments.

### BRIEF DESCRIPTION OF DRAWINGS

In order to illustrate the technical solutions in the embodiments of the present application or in the prior art more clearly, the following briefly introduces the accompanying drawings required for describing the embodiments or the prior art. Apparently, the accompanying drawings in the following description are some embodiments of the present application, and for those skilled in the art, other drawings may also be obtained according to these drawings without creative efforts.

FIG. 1a is a schematic structural diagram of a heat dissipation member provided by an embodiment of the present application.

FIG. 1b is a schematic structural diagram of an electronic assembly provided by an embodiment of the present application.

FIG. 2 is another schematic structural diagram of an electronic assembly provided by an embodiment of the present application.

FIG. 3 is another schematic structural diagram of an electronic assembly provided by an embodiment of the present application.

FIG. 4 is another schematic structural diagram of an electronic assembly provided by an embodiment of the present application.

FIG. 5 is another schematic structural diagram of an electronic assembly provided by an embodiment of the present application.

FIG. 6 is another schematic structural diagram of an electronic assembly provided by an embodiment of the present application.

FIG. 7 is another schematic structural diagram of an electronic assembly provided by an embodiment of the present application.

FIG. 8 is another schematic structural diagram of an electronic assembly provided by an embodiment of the present application.

FIG. 9 is another schematic structural diagram of an electronic assembly provided by an embodiment of the present application.

FIG. 10 is another schematic structural diagram of an electronic assembly provided by an embodiment of the present application.

FIG. 11 is another schematic structural diagram of an electronic assembly provided by an embodiment of the present application.

FIG. 12 is another schematic structural diagram of an electronic assembly provided by an embodiment of the present application.

FIG. 13a is another schematic structural diagram of an electronic assembly provided by an embodiment of the present application.

FIG. 13b is another schematic structural diagram of an electronic assembly provided by an embodiment of the present application.

FIG. 13c is another schematic structural diagram of an electronic assembly provided by an embodiment of the present application.

FIG. 14 is another schematic structural diagram of an electronic assembly provided by an embodiment of the present application.

FIG. 15 is another schematic structural diagram of an electronic assembly provided by an embodiment of the present application.

FIG. 16 is another schematic structural diagram of an electronic assembly provided by an embodiment of the present application.

FIG. 17 is another schematic structural diagram of an electronic assembly provided by an embodiment of the present application.

FIG. 18 is another schematic structural diagram of an electronic assembly provided by an embodiment of the present application.

FIG. 19 is another schematic structural diagram of an electronic assembly provided by an embodiment of the present application.

FIG. 20 is a schematic structural diagram of a heating component provided by an embodiment of the present application.

### DESCRIPTION OF THE REFERENCE NUMBERS

100: electronic assembly; 110: heat dissipation member;
111/121: first surface; 112/122: second surface;
1121: inclined plane; 1122: curved surface;
1123: auxiliary plane; 113: flow passage;
120: heating component; 1201: first heating component;
1202: second heating component; 131: first auxiliary heat-dissipation member;
132: second auxiliary heat-dissipation member; 1321: first extension portion;
1322: second extension portion; 133: auxiliary heat-dissipation member;
140: circuit board.

### DESCRIPTION OF EMBODIMENTS

In the related art, a phase-change-immersion liquid heat-dissipation module may include a housing, phase-change cooling liquid, a condensing coil and an electronic assembly, where the housing has an accommodating cavity, and the phase-change cooling liquid, the condensing coil and the electronic are all located in the accommodating cavity. The phase-change cooling liquid is located at a bottom of the accommodating cavity, the electronic assembly is immersed in the phase-change cooling liquid, and the condensing coil is located at a top of the accommodating cavity and spaced from the phase-change cooling liquid. The electronic assembly may include a circuit board, a heating component and/or a heat dissipation member. When the temperature of the heat dissipation member/heating component exceeds the saturation temperature of the phase-change cooling liquid and reaches a certain value, for example, degree of superheat of 4° C. to 26° C., the bubble is generated at a vaporization core located on a surface of the heat dissipation member/the heating component. After being generated, the bubble continuously grows, separates and floats upwards. At least part of the bubbles absorb a large amount of latent heat of vaporization during a process of generation and growth, and the separation and rising movement of the bubbles produce violent disturbance, so that the boiling is gradually violent, and the heat transfer coefficient and the heat flux density are sharply increased, and nucleate boiling state or transition boiling state is achieved. In a floating process of the bubbles in the liquid, if the cooling liquid does not reach its saturation temperature, the bubbles float to the liquid and break and disappear; if the cooling liquid reaches its saturation temperature, the bubbles float to a liquid surface and break, and the cooling liquid is vaporized into vapor. After the rising vapor contacts with the condensing coil for heat exchange and being cooled, the vapor is liquefied to form small droplets and drop down. In this way, the circulation is repeated to achieve cooling of the heating component. For example, a bottom surface of the heat dissipation member may be provided with a plurality of heat dissipation fins, the heat dissipation fin extends along a vertical direction, and two adjacent heat dissipation fins are spaced apart from each other. Both the bottom surfaces of the heat dissipation member and the heat dissipation fin may extend along a horizontal direction.

However, when the heating component and/or the heat dissipation member thereof are located at a bottom surface of the circuit board, bottom surfaces of the heating component and/or the heat dissipation member and/or the heat dissipation fin constitute the heating surface in phase-change-and-cooling liquid, the bubbles are continuously generated at the vaporization core on the heating surface, but a force enabling the bubble to separate cannot be generated because the heating surface is horizontally arranged. The bubble continuously grows after absorbing heat, and when growing to a certain diameter, that is, a separating diameter of the bubble, the bubble slides away along the heating surface. In this case, the speed of the bubble separating from the heating surface is very slow, and the bubble cannot separate from the lower surface of the heating component or the heat dissipation member in time. With the growing and increasing of bubbles generated by boiling, the bubbles gather at the bottom surfaces of the heat dissipation member and the heat dissipation fin, and form a large bubble. The large bubble covers the heating surface in a flat shape, which hinders direct heat exchange between the heating surface and the cooling liquid, and causes that the heat transfer coefficient is decreased, thereby resulting that a heat dissipation effect on the heating component is poor.

Based on at least one technical problem mentioned above, in a gravity coordinate system, an embodiment of the present application provides a heating component, an electronic assembly and a heat dissipation assembly. The heat dissipation member is configured for the heating component. The heat dissipation member includes a first surface and a second surface which are oppositely disposed along a gravity direction, where the first surface is located above the second surface. An extending direction of at least a part of the second surface is different from a horizontal direction. The first surface is located below the heating component, and at least a part of the second surface is disposed to be immersed in phase-change cooling liquid. In this way, by setting the extending direction of the at least a part of the second surface of the heat dissipation member, which is immersed in the phase-change cooling liquid, to be different from the horizontal direction, when a bubble is generated at a vaporization core of the at least a part of the second surface, a force enabling the bubble to separate is generated, so that it is easily for the bubble to separate from the at least a part of the second surface, and the speed of the bubble separating from the second surface is accelerated, thereby alleviating a hindrance of a large bubble in heat exchange between the heating surface and the cooling liquid, improving the boiling-and-heat-transfer coefficient, and improving the heat dissipation effect of the phase-change cooling liquid on the heat dissipation member, the heating component and the electronic assembly, so as to avoid damaging the heating component and improve the heat dissipation effect of the device.

In order to make the objectives, technical solutions and advantages of the embodiments of the present application clearer, the following clearly and completely describes the technical solutions in the embodiments of the present application with reference to the accompanying drawings in embodiments of the present application. Apparently, the described embodiments are merely a part rather than all of the embodiments of the present application. Based on the embodiments of the present application, all other embodiments obtained by persons of ordinary skill in the art without creative efforts shall belong to the scope of protection of the present application.

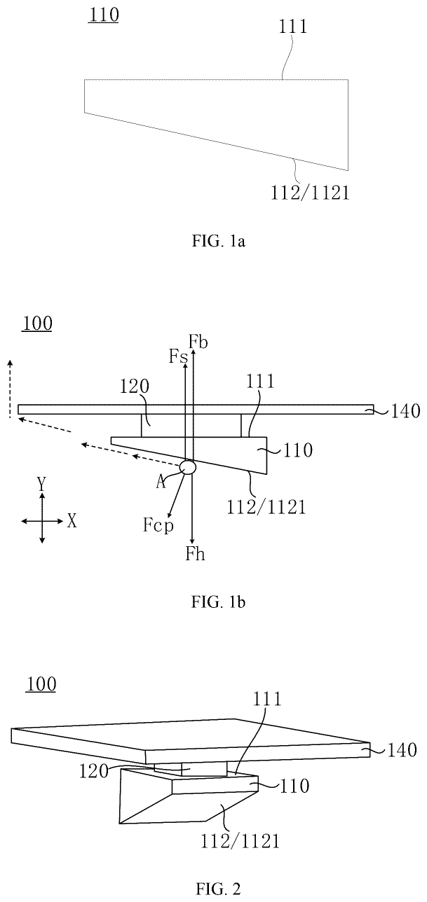

The following describes the heat dissipation member 110 provided by the embodiment of the present application with reference to FIG. 1a to FIG. 20.

Referring to FIG. 1b, an embodiment of the present application provides a heat dissipation member 110, where the heat dissipation member 110 may be configured for providing heat dissipation of a heating component 120. In a gravity coordinate system, the heat dissipation member 110 may include a first surface 111 and a second surface 112 which are oppositely disposed along a gravity direction Y, and the first surface 111 may be located above the second surface 112. The first surface 111 may be located below the heating component 120, and the heating component 120 may be directly connected with the first surface 111 or indirectly connected with the first surface 111, for example, indirectly connected through a thermal interface material. At least a part of the second surface 112 is disposed to be immersed in phase-change cooling liquid, for example, the second surface 112 may be entirely immersed in the phase-change cooling liquid. Heat of the heating component 120 may be transferred to the heat dissipation member 110, and the phase-change cooling liquid may produce boiling-and-heat-exchange to take away the heat of the heat dissipation member 110 through the immersed at least a part of the second surface 112, thereby implementing heat dissipation of the heating component 120. It should be noted that, a space arrangement manner of the heat dissipation member in all embodiments of the present application in practical applications includes, but is not limited to, disposition along the gravity direction.

In some embodiments, the extending direction of at least a part of the second surface 112 is different from the horizontal direction X. By setting the extending direction of the at least a part of the second surface 112, which is immersed in the phase-change cooling liquid, to be different from the horizontal direction X, when a bubble is generated at a vaporization core of the at least a part of the second surface 112, a force enabling the bubble to separate is generated, so that it is easily for the bubble to separate from the at least a part of the second surface 112, and the speed of the bubble separating from the at least a part of the second surface 112 is accelerated. After separating, the bubble is taken away by turbulence, thereby alleviating a hindrance of a large bubble in heat exchange between the second surface 112 and the cooling liquid, improving the boiling-and-heat-exchange coefficient, and greatly enhancing the heat dissipation capability, so that the phase-change cooling liquid may effectively take away the heat of the heat dissipation member 110, the heat dissipation effect of the phase-change cooling liquid on the heat dissipation member 110 and the heating component 120 is improved, thereby avoiding damage to the heating component 120.

Exemplarily, a material of the heat dissipation member 110 may be a metal material (such as copper, aluminum or the like), and may also be a non-metal material (such as plastic packaging material, plastic, glass, ceramic or the like). The embodiment of the present application does not limit the material of the heat dissipation member 110.

Exemplarily, thermal conductivity of the heat dissipation member 110 may be greater than or equal to 20 W/(m*k), so that the heat dissipation member 110 may perform better heat exchange with the heating component 120 and the phase-change cooling liquid, but the thermal conductivity is not limited thereto. For example, the thermal conductivity of the heat dissipation member 110 may be 20 W/(m*k), 25 W/(m*k), 30 W/(m*k), 35 W/(m*k), 40 W/(m*k), or any value greater than 30 W/(m*k).

The second surface 112 provided by the embodiment of the present application is described in detail below.

In some embodiments, referring to FIG. 1b, FIG. 8 and FIG. 14, the second surface 112 may include at least one of an inclined plane 1121 which is obliquely intersected with the first surface 111 and a curved surface 1122. When a bubble is generated at a vaporization core of the inclined plane 1121 and/or the curved surface 1122, a force enough to enable the bubble to separate may be generated, so that it is easily for the bubble to separate from the inclined plane 1121 and/or the curved surface 1122, and the separating speed of the bubble is accelerated. After separating, the bubble is taken away by turbulence, thereby alleviating a hindrance of a large bubble in heat exchange between the heating surface and the liquid working medium, and improving the boiling-and-heat-exchange coefficient, so that the phase-change cooling liquid may effectively take away the heat of the heat dissipation member 110, the heat dissipation effect of the phase-change cooling liquid on the heat dissipation member 110 and the heating component 120 is improved, thereby avoiding damage to the heating component 120.

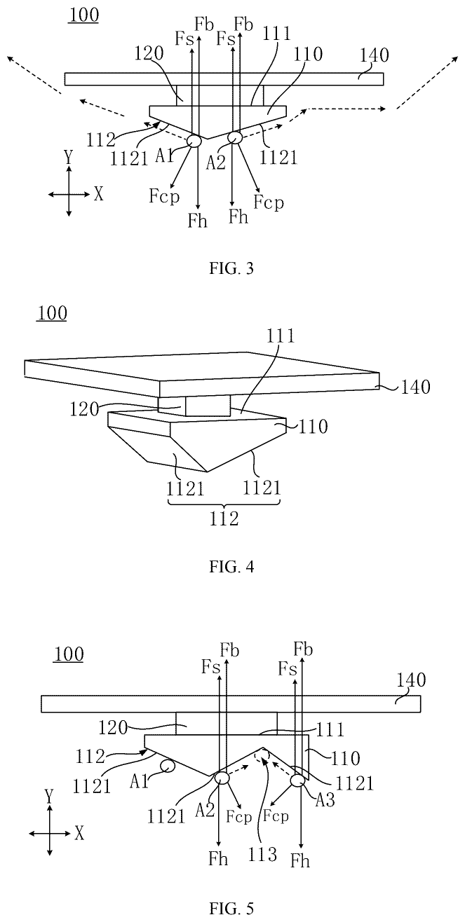

In an embodiment where the second surface 112 includes the inclined plane(s) 1121, the number of inclined planes 1121 may be one (FIG. 1b), two (FIG. 3), three (FIG. 5), or more than three (FIG. 7). For example, the second surface 112 may include a plurality of inclined planes 1121, and the plurality of inclined planes 1121 may form a zigzag shape.

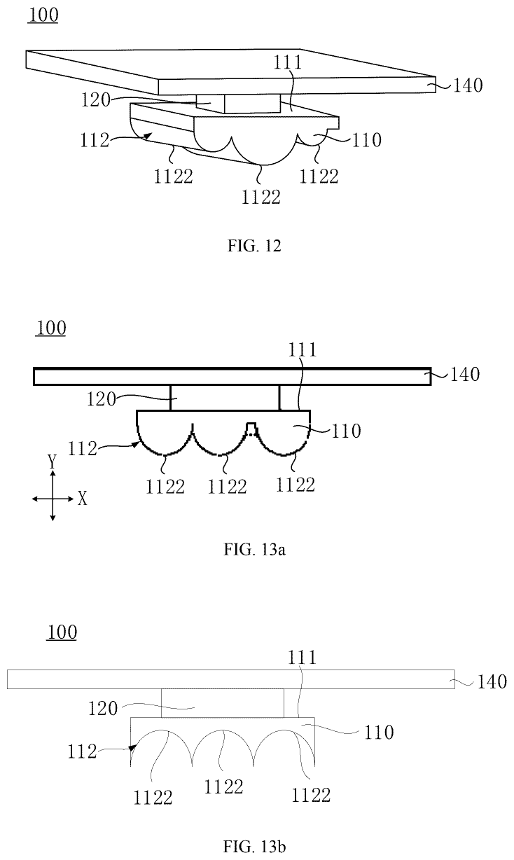

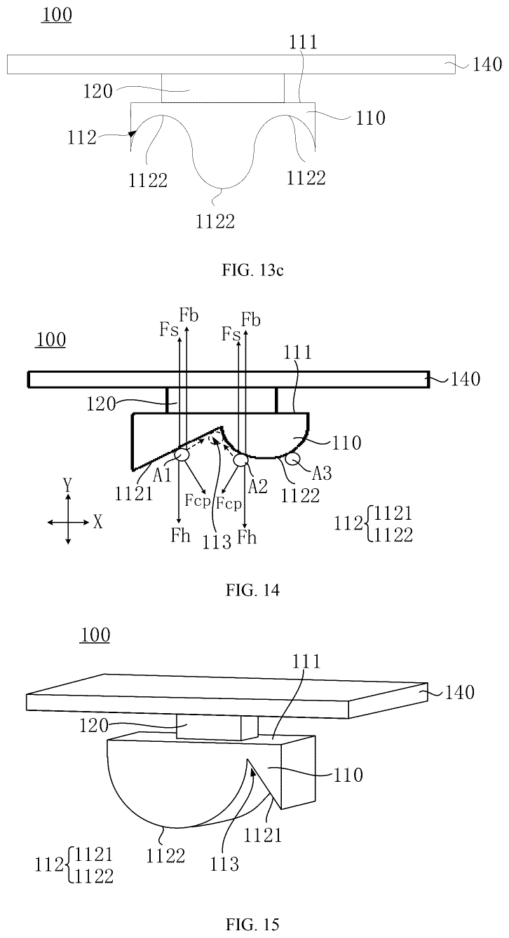

In an embodiment where the second surface 112 includes the curved surface(s) 1122, the number of curved surfaces 1122 may be one (FIG. 8), two (FIG. 10), three (FIG. 12), or more than three (FIG. 13a). For example, the second surface 112 may include a plurality of curved surfaces 1122, and the plurality of curved surfaces 1122 may form a wave shape. For example, a single curved surface 1122 may be a smooth continuous curved surface, including at least one of a convex curved surface and a concave curved surface. As shown in FIG. 13b, the curved surface 1122 may be a concave curved surface, the concave curved surface refers to that a certain curved surface 1122 of the second surface 112 is concave inwards in a direction close to the first surface 111 by taking the first surface 111 of the heat dissipation member 110 as a reference, and the curved surface 1122 is the concave curved surface. Referring to FIG. 13a, the curved surface 1122 may be a convex curved surface, the convex curved surface refers to that a certain curved surface 1122 of the second surface 112 is convex outwards in a direction away from the first surface 111 by taking the first surface 111 of the heat dissipation member 110 as a reference, and the curved surface 1122 is the convex curved surface. FIG. 13c shows that a plurality of curved surfaces 1122 include concave curved surfaces and the convex curved surface.

In an embodiment where the second surface 112 includes the inclined plane 1121, an included angle between the inclined plane 1121 and the horizontal direction X may be greater than or equal to 10 degrees, so that it may be more easily for the bubble to separate from the inclined plane 1121, and it may be more easily for the bubble to separate from the heat dissipation member 110. For example, the included angle can be 10 degrees, 15 degrees, 20 degrees, or any value greater than 10 degrees. The larger the included angle is, the easier it is for the bubble to separate from the heating surface, the shorter the separation period of the bubble to separate from the heating surface is, and the higher a boiling-and-heat-transfer coefficient is. With the increase of the included angle, the separation period of the bubble gradually decreases. Where when the included angle is 5 degrees, the separation period of the bubble is stable at about 0.27 s; when the included angle is 30 degrees, 45 degrees, 60 degrees and 90 degrees, the separation period of the bubble is stable at 0.21 s, 0.19 s, 0.15 s and 0.13 s, respectively. According to results of theoretical calculation, for a specific downward plane of the heating surface, the superheat degree is 30° C., and if the heating surface is horizontally arranged, the boiling-and-heat-transfer coefficient is approximately 2000 W/(m2·k); if an inclined included angle of the heating surface is 10 degrees, the separation of the bubble is obvious, and the boiling-and-heat-transfer coefficient is significantly increased, which are increased by about 20%. When the included angle is less than 10 degrees, the separation of the bubble is not obvious enough, and the boiling-and-heat-transfer coefficient increases slightly.

In an embodiment where the second surface 112 includes the curved surface 1122, curvature of the curved surface 1122 may be greater than or equal to 0.00264, thereby making it more easily for the bubble to separate from the curved surface 1122, so that it may be more easily for the bubble to separate from the heat dissipation member 110. When the curvature is less than 0.00264, the separation of the bubble is not obvious enough, and the boiling-and-heat-transfer coefficient increases slightly. For example, the curvature may be 0.00264, 0.00284, 0.00300, or any value greater than 0.00264. According to results of theoretical calculation, for a specific downward plane of the heating surface, the superheat degree is 30° C., the heating surface is a plane, and the boiling-and-heat-transfer coefficient is approximately 2000 W/(m2·k); when the curvature of the curved-surface heating surface is 0.00264, the boiling-and-heat-transfer coefficient increases by about 15%. The larger the curvature is, the easier it is for the bubble to separate from the heating surface, the shorter the separation period of the bubble to separate from the heating surface is, and the higher the boiling-and-heat-transfer coefficient is.

Exemplarily, a size of the inclined plane 1121 and/or the curved surface 1122 may be set to be relatively large, to facilitate to implement external processing of the heat dissipation member through common processing technology of the heat dissipation member, without additional processing procedures to perform surface micro-processing, so that the technology is simple and the operation is convenient. For example, the inclined plane 1121 has a first projection on the first surface 111 along a direction perpendicular to the first surface 111, and a distance between the arbitrary two points in the first projection may be greater than or equal to 0.3 mm, for example, the distance between the arbitrary two points may be 0.3 mm, 0.5 mm, 0.7 mm, 1 mm, or any value greater than 0.3 mm. These two points are not real existing points, but is used to represent a characteristic length size on the heat dissipation surface. Further, there is a projection plane in the first projection, its characteristic length is greater than or equal to 0.3 mm, and the characteristic length=4*area of the projection plane/perimeter of the projection plane. The inclined plane 1121 may include a first edge and a second edge, the first edge is defined as disposed closer to the first surface 111 relative to the second edge, and the arbitrary two points may be respectively located on the first projection of the first edge and the first projection of the second edge, or the arbitrary two points may be located between the first projection of the first edge and the first projection of the second edge.

For example, the curved surface 1122 has a first projection on the first surface 111 in a direction perpendicular to the first surface 111, there are arbitrary two points in the first projection, and a distance between the arbitrary two points may be greater than or equal to 0.3 mm. The principle thereof is similar to that of the inclined plane 1121 and is not described again.

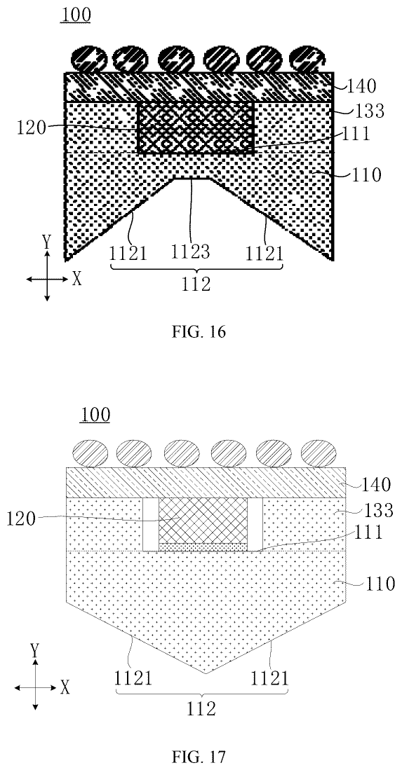

Exemplarily, referring to FIG. 16, the second surface 112 may include a plane parallel to the first surface 111 (namely, auxiliary plane 1123), and the number of auxiliary planes 1123 may be at least one, so that the shape of the second surface 112 is more diversified, and the shape of the second surface 112 may be flexibly selected to meet requirements of different scenarios or different products. For example, the second surface 112 may be a combination of the auxiliary plane 1123 and the inclined plane 1121, or the second surface 112 may be a combination of the auxiliary plane 1123 and the curved surface 1122, or the second surface 112 may be a combination of the auxiliary plane 1123, the inclined plane 1121 and the curved surface 1122, but not limited thereto.

Exemplarily, referring to FIG. 5, FIG. 10 and FIG. 14, the second surface 112 may include a plurality of sub-surfaces, and the plurality of sub-surfaces may include the inclined plane 1121 and/or the curved surface 1122, where any sub-surface may be an inclined plane 1121 or a curved surface 1122. The extending directions of two adjacent sub-surfaces may be different, a flow passage 113 may be formed between at least a part of the two adjacent sub-surfaces, and the phase-change cooling liquid near the flow passage 113 may produce relative movement along the extending direction of the flow passage 113, that is, a direction perpendicular to the paper surface, thereby being conducive to drive the bubble in the flow passage 113 to leave the flow passage 113 and escape from the sub-surfaces at the flow passage 113. The two adjacent sub-surfaces may be directly connected, or the two adjacent sub-surfaces may be connected through the auxiliary plane 1123. For example, referring to FIG. 16, the auxiliary plane 1123 may be disposed between the two adjacent inclined planes 1121. In other examples, referring to FIG. 1b, the second surface 112 may be an inclined plane 1121, or, referring to FIG. 8, the second surface 112 may be a curved surface 1122.

Exemplarily, a roughness of the second surface 112 may be greater than or equal to 0.01 mm and less than or equal to 0.3 mm, which may increase the effective area for boiling-and-heat-transfer of the second surface 112, increase the vaporization cores, and greatly enhance the boiling-and-heat-exchange capability. The roughness of the second surface 112 may be 0.01 mm, 0.02 mm, 0.05 mm, 0.1 mm, 0.15 mm, 0.2 mm, 0.25 mm, 0.3 mm, or any value between 0.01 mm and 0.3 mm. Taking the second surface 112 including the inclined plane 1121 (FIG. 1b) as an example, the roughness of the inclined plane 1121 may range from 0.01 mm to 0.3 mm. When the second surface 112 includes the curved surface 1122 (FIG. 8) and/or the auxiliary plane 1123 (FIG. 16), the roughness of the curved surface 1122 and/or the auxiliary plane 1123 is similar to that of the inclined plane 1121. For example, the microscopic geometry of the second surface 112 may be changed by gluing rough-surface materials on the surface, adding porous structures on the surface, adding micro-cavities on the surface, using metal foam materials or micro-porous coatings, or the like.

The following describes the bubble escaping from the inclined plane 1121 provided by an embodiment of the present application.

Exemplarily, referring to FIG. 1b and FIG. 2, the second surface 112 may be an inclined plane 1121. The inclined plane 1121 may include a first end and a second end which are located in the extending direction, and the first end is obliquely disposed in a direction close to the first surface 111 relative to the second end, or the first end is obliquely disposed in a direction away from the first surface 111 relative to the second end. A cross section of the heat dissipation member 110 along a direction perpendicular to the first surface 111 may be, but is not limited to, a trapezoid, a triangle, or the like. When bubble A is generated at the vaporization core of the inclined plane 1121, the bubble A grows to a certain size, and forces on the bubble A is shown in FIG. 1b, where Fb is buoyancy of water to the bubble A (the buoyancy is a pressure difference generated by still water on upper and lower surfaces of an object), Fs is shear force (namely, a force generated due to the bubble being affected by the near-wall velocity field), Fh is hydraulic pressure (namely, a pressure generated by the water flowing pressure on the bubble), and Fcp is contact pressure applied on the bubble A by the inclined plane 1121. Fb, Fs, Fh and Fcp form a resultant force applied on the bubble A. The direction of the resultant force is different from the normal direction of the inclined plane 1121. Under the action of the resultant force, it is more easily for the bubble A to separate from the inclined plane 1121, and is taken away by the turbulence after being separated. The escape direction may be perpendicular to the paper surface, and may also be other directions, because the turbulence is random and disordered. The turbulence is mainly caused by driven of temperature difference and the separating and rising movement of the bubble. Then the bubble rises and grows, and finally breaks. The dotted arrow in FIG. 1b shows a possible escape path of the bubble A.

Exemplarily, referring to FIG. 3 and FIG. 4, the second surface 112 may include two inclined planes 1121, and inclined directions of the two inclined planes 1121 are different. Both the two inclined planes 1121 include a first end and a second end in the extending direction, and the two inclined planes 1121 may be a first inclined plane and a second inclined plane. The second end of the first inclined plane is connected with the first end of the second inclined plane, the first end of the first inclined plane is obliquely disposed in a direction close to the first surface 111 relative to the second end, and the first end of the second inclined plane is obliquely disposed in a direction away from the first surface 111 relative to the second end. A cross section of the heat dissipation member 110 along a direction parallel to the first surface 111 may be a pentagon, a triangle, etc. The lengths of the first inclined plane and the second inclined plane may be set in any proportion. When bubble A1 and bubble A2 are generated at the vaporization cores of the two inclined planes 1121, the bubble A1 and the bubble A2 grow to a certain size, and the forces on the bubble A1 and the bubble A2 are shown in FIG. 3, where Fb is the buoyancy, Fs is the shear force, Fh is the hydraulic pressure, and Fcp is the contact pressure. Fb, Fs, Fh and Fcp collectively form a resultant force. The direction of the resultant force is different from the normal direction of the inclined plane 1121. Under the action of the resultant force, it is more easily for the bubble A1 and the bubble A2 to separate from the two inclined planes 1121, respectively, and are taken away by the turbulence after being separated. Then the bubbles rise and grow, and finally break. Possible escape paths of the bubble A1 and the bubble A2 are indicated by the dotted arrows in FIG. 3.

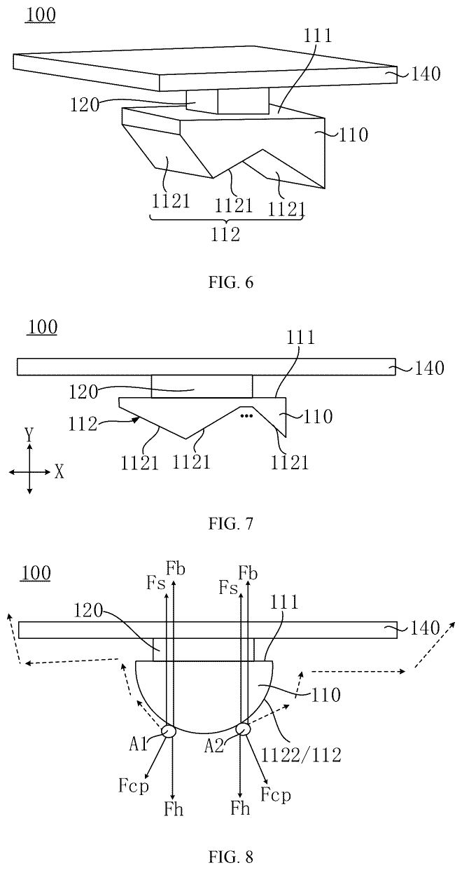

Exemplarily, referring to FIG. 5 and FIG. 6, the second surface 112 may include three inclined planes 1121, the three inclined planes 1121 are sequentially connected end to end, and the three inclined planes 1121 form a zigzag shape. The three inclined planes 1121 are a first inclined plane corresponding to the bubble A1, a second inclined plane corresponding to the bubble A2, and a third inclined plane corresponding to the bubble A3, respectively. A flow passage 113 is formed between the second inclined plane and the third inclined plane. When bubbles are generated at the vaporization cores of the second surface 112, the bubbles grow to a certain size, the escape path of the bubble A1 is similar to that of the above example. The forces on the bubble A2 and the bubble A3 are shown in FIG. 5, where Fb is the buoyancy, Fs is the shear force, Fh is the hydraulic pressure, and Fcp is the contact pressure. Fb, Fs, Fh and Fcp collectively form a resultant force. The direction of the resultant force is different from the normal direction of corresponding inclined plane 1121. The bubble A2 and the bubble A3 are respectively separated from the second inclined plane and the third inclined plane under the action of corresponding resultant force. With the oscillation of the turbulence when the phase-change cooling liquid boils, finally the bubbles are carried away by the turbulence along the extending direction of the flow passage 113 (for example, the direction perpendicular to the paper surface in FIG. 5) or other directions. Possible escape paths of the bubble A2 and the bubble A3 are indicated by the dotted arrows in FIG. 5. Generally, a flow direction of the cooling liquid is along the extending direction of the flow passage 113 (for example, the direction perpendicular to the paper surface in FIG. 5). A part of the bubbles are carried away along the flow direction of the cooling liquid, and a part of the bubbles are carried away along other directions, because the turbulence is random and disordered. Generally, there is a gap between the circuit board and the accommodating cavity of the cooling liquid. The bubbles are carried away by the water flow during the rising process, and when the gap is relatively small, the bubble is squeezed and breaks in the water. In a floating process of the bubbles in the cooling liquid, if the cooling liquid does not reach its saturation temperature, the bubbles float to the liquid and break and disappear; if the cooling liquid reaches its saturation temperature, the bubbles float to a liquid surface and break, and the cooling liquid is vaporized into vapor. After rising and contacting with the condensing coil for heat exchange and being cooled, the vapor is liquefied to drop down. In this way, the circulation is repeated to achieve cooling of the heating component.

The following describes the bubble escaping from the curved surface 1122 provided by an embodiment of the present application.

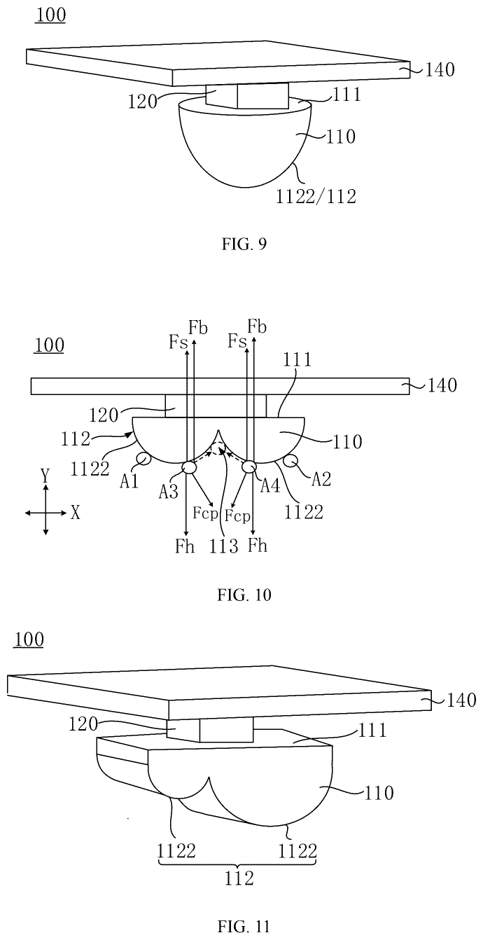

Exemplarily, referring to FIG. 8 and FIG. 9, the second surface 112 may be a curved surface 1122 (namely, a single curved surface), and the curved surface 1122 is curved in a direction away from the first surface 111. For example, the curved surface 1122 may be a paraboloid, a sphere, or the like. When bubbles are generated at the vaporization core of the curved surface 1122, the bubble grows to a certain size, the force on the bubble is as shown in FIG. 8, where Fb is the buoyancy of water on the bubble A1 and the bubble A2, Fs is the shear force, Fh is the hydraulic pressure, and Fcp is the contact pressure. Fb, Fs, Fh and Fcp form a resultant force. The direction of the resultant force is different from the normal direction of corresponding curved surface 1122. Under the action of the resultant force, it is more easily for the bubble A1 and the bubble A2 to separate from the second surface 112, and are taken away by the turbulence after being separated, and then rise and grow, and finally break up. There are two possible escape paths of the bubbles indicated by the dotted arrows in FIG. 8.

Referring to FIG. 10 and FIG. 11, the second surface 112 may be two curved surfaces 1122, the curved surfaces 1122 are curved in a direction away from the first surface 111, and a flow passage 113 is formed between the two curved surfaces 1122. When bubbles are generated at the vaporization cores of the two curved surfaces 1122, the bubbles grow to a certain size, and the escape paths of the bubble A1 and the bubble A2 are similar to the escape paths of the bubbles in FIG. 8. The forces on the bubble A3 and the bubble A4 are shown in FIG. 10, where Fb is the buoyancy, Fs is the shear force, Fh is the hydraulic pressure, and Fcp is the contact pressure. Fb, Fs, Fh and Fcp collectively form a resultant force. The direction of the resultant force is different from the normal direction of corresponding curved surface 1122. Under the action of the resultant force, the bubble A3 and the bubble A4 are separated from the corresponding curved surface 1122. With the oscillation of the turbulence when the phase-change cooling liquid boils, finally the bubbles are carried away by the turbulence along the extending direction of the flow passage 113 (for example, the direction perpendicular to the paper surface in FIG. 10) or other directions. Possible escape paths of the bubble A3 and the bubble A4 are indicated by the dotted arrows in FIG. 10.

The following describes the bubble escaping from the inclined plane 1121 and the curved surface 1122 provided by the embodiment of the present application.

Referring to FIG. 14 and FIG. 15, the second surface 112 may be a combination of the inclined plane 1121 and the curved surface 1122. When bubbles are generated at vaporization cores of the inclined plane 1121 and the curved surface 1122, the bubbles grow to a certain size, the escape path of the bubble A3 is similar to the escape path of the bubble in FIG. 8. The forces on the bubble A1 and the bubble A2 are shown in FIG. 14, where Fb is the buoyancy, Fs is the shear force, Fh is the hydraulic pressure, and Fcp is the contact pressure. A direction of a resultant force on the bubble A1 is different from the normal direction of the inclined plane 1121, that is, not perpendicular to the inclined plane. A direction of a resultant force on the bubble A2 is different from the normal direction of the curved surface 1122. under the action of the corresponding resultant force, the bubble A1 and the bubble A2 are respectively separated from the inclined plane 1121 and the curved surface 1122, and after being separated, they are subjected to the oscillation of the turbulence when the phase-change cooling liquid boils, and are taken away by the turbulence. Generally, a flow direction of the cooling liquid is along the extending direction of the flow passage 113 (for example, the direction perpendicular to the paper surface in FIG. 14). A part of bubbles are carried away along the flow direction of the cooling liquid, and a part of bubbles are carried away along other directions, because the turbulence is random and disordered. Generally, there is a gap between the circuit board and the accommodating cavity of the cooling liquid. The bubbles are carried away by the water flow during the rising process, and when the gap is relatively small, the bubble is squeezed and breaks in the water. In a floating process of the bubbles in the cooling liquid, if the cooling liquid does not reach its saturation temperature, the bubbles float to the liquid and break and disappear; if the cooling liquid reaches its saturation temperature, the bubbles float to a liquid surface and break, and the cooling liquid is vaporized into vapor. After rising and contacting with the condensing coil for heat exchange and being cooled, the vapor is liquefied to drop down. In this way, the circulation is repeated to achieve cooling of the heating component. Possible escape paths of the bubble A1 and the bubble A2 are indicated by the dotted arrows in FIG. 14.

The following describes the first surface 111 provided by the embodiment of the present application.

In some embodiments, with reference to FIG. 1b, the first surface 111 may be a plane, for example, flatness of the first surface 111 may be less than or equal to 0.1 mm, so that the first surface 111 and the heating component 120 may be closely attached. For example, a thermal interface material may be disposed between the first surface 111 and the heating component 120, or the first surface 111 and the heating component 120 may be directly connected, thereby reducing an interface thermal resistance and facilitating heat dissipation of the heating component 120. For example, the flatness of the first surface 111 may be 0.01 mm, 0.05 mm, 0.07 mm, 0.1 mm, or any value less than 0.1 mm. The smaller the flatness is, the thinner the thermal interface material is, thereby reducing the interface thermal resistance and facilitating heat dissipation of the heating component 120. In other embodiments, at least a part of the first surface 111 may be a non-plane. The shape of the first surface 111 is not limited in the embodiment of the present application. The embodiment of the present application takes the first surface 111 being a plane as an example to describe.

Exemplarily, referring to FIG. 1b, the first surface 111 may be parallel to the horizontal direction X, so that coordinate between the first surface 111 and another structural member is relatively simple, and installation difficulty of the heat dissipation member 110 may be reduced.

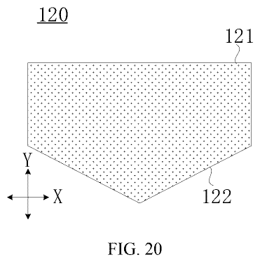

Referring to FIG. 20, the embodiment of the present application further provides a heating component 120, which generates heat under operation. The heating component 120 may include a first surface 121 and a second surface 122 which are oppositely disposed along a gravity direction Y. The first surface 121 may be located above the second surface 122. At least a part of the second surface 122 is an inclined plane which is obliquely intersected with the horizontal direction X and/or a curved surface, and at least a part of the second surface 122 is disposed to be immersed in phase-change cooling liquid. Heat of the heating component 120 may be directly taken away by the phase-change cooling liquid through the second surface 122, thereby implementing heat dissipation of the heating component 120. By setting the at least a part of the second surface 122 to be the inclined plane and/or the curved surface, the hindrance of a large bubble in heat exchange between the second surface 122 and the liquid working medium may be alleviated, thereby improving boiling-and-heat-transfer coefficient, and improving the heat dissipation effect of the phase-change cooling liquid on the heating component 120. The principle is similar to that of the heat dissipation member 110 in the foregoing embodiments, and is not described again.

In some implementations, the arrangement manners of the first surface 121 and the second surface 122 of the heating component 120 thereof may be similar to that of the heat dissipation member 110 in the foregoing embodiments, and are not described again. In other implementations, the heating component 120 has a packaging structure, it includes a pre-produced device and the heat dissipation member, which the heating component 120 is in form of an open-frame assembly or an encapsulated body. The arrangement manners form the whole first surface 121 and the second surface 122 of it after packaging may be similar to that of the heat dissipation member 110 in the foregoing embodiments. The heating component may be, but is not limited to, an electronic component, such as a chip, a resistor, a capacitor, an inductor, a power supply module, or the like.

The following describes the electronic assembly 100 provided by an embodiment of the present application.

Referring to FIG. 1b, the embodiment of the present application provides an electronic assembly 100. The electronic assembly 100 may include the heating component 120 and the heat dissipation member 110 in the foregoing embodiments. The heating component 120 may be located on the first surface 111 of the heat dissipation member 110. Heat of the heating component 120 may be transferred to the heat dissipation member 110, and the phase-change cooling liquid may take away the heat of the heat dissipation member 110 through a second surface 112 of the heat dissipation member 110, thereby implementing heat dissipation of the heating component 120. By setting an extending direction of at least a part of the second surface 112, which is immersed in the phase-change cooling liquid, to be different from the horizontal direction X, a hindrance of a large bubble in heat exchange between the second surface 112 and the liquid working medium may be alleviated, thereby improving boiling-and-heat-transfer coefficient, and improving the heat dissipation effect of the phase-change cooling liquid on the heat dissipation member 110, the heating component 120 and the electronic assembly 100, so that the heat dissipation effect of the device is better. The principle has been described, and is not described again.

Exemplarily, the heating component 120 may include at least one of an electronic component, a chip, a power supply module, or the like. The embodiment of the present application does not limit the type of the heating component 120. Taking the heating component 120 including the electronic component as an example, the number of the electronic component is one or more, and the electronic component may be a transistor, such as a metal-oxide-semiconductor field-effect transistor (Metal-Oxide-Semiconductor Field-Effect Transistor, MOSFET for short). Taking the heating component 120 including the chip as an example, the chip may be a silicon chip, a silicon carbide or gallium nitride chip, and other types of semiconductor integrated circuit carriers.

Exemplarily, referring to FIG. 1b, the electronic assembly 100 may include a circuit board 140, and a surface of the heating component 120, which is away from the first surface 111, is adjacent to a surface of the circuit board 140, that is, the heating component 120 and the circuit board 140 may be in direct contact or in indirect contact (for example, in indirect contact through a heat conducting material), which helps reduce the total volume of the heating component 120 and the circuit board 140. For example, a thickness direction of the circuit board 140 may be parallel to the gravity direction Y, so that the installation of the circuit board 140 is relatively easy in practical applications.

In some embodiments, referring to FIG. 16 and FIG. 17, the electronic assembly 100 may include an auxiliary heat-dissipation member 133, the auxiliary heat-dissipation member 133 may be located between the first surface 111 and the circuit board 140, and is annularly disposed around at least a part of periphery of the heating component 120. The auxiliary heat-dissipation member 133 may increase heat dissipation area of the heat dissipation member 110, thereby facilitating to improve the heat dissipation effect. For example, the auxiliary heat-dissipation member 133 may be annularly disposed around a part of the periphery of the heating component 120, the auxiliary heat-dissipation member 133 may be located at two opposite sides of the heating component 120, and the shapes of the heat dissipation member 110 and the auxiliary heat-dissipation member 133 may be U-shaped. For another example, the auxiliary heat-dissipation member 133 may be annularly disposed around an entire periphery (for example, all around) of the heating component 120. The auxiliary heat-dissipation member and the heat dissipation member may be integrally disposed or separately disposed.

Exemplarily, roughness of a side wall of the auxiliary heat-dissipation member 133 and/or a side wall of the heat dissipation element 110 may range from 0.01 mm to 0.3 mm, so that effective area of boiling-and-heat-transfer of the side wall may be increased, the vaporization cores may be increased, and the boiling-and-heat-exchange capability is greatly enhanced. The principle has been described, and is not described again.

Exemplarily, in order to further increase the heat dissipation area and improve the heat dissipation capability, at least one of the side wall of the auxiliary heat-dissipation member 133, the side wall of the heat dissipation member 110 and the second surface 112 may be provided with a heat dissipation fin, and the number of the heat dissipation fins may be at least one. When there are a plurality of heat dissipation fins, there may be a spacing between two adjacent heat dissipation fins. Types of any two heat dissipation fins may be the same or different.

Exemplarily, referring to FIG. 16 and FIG. 17, in an implementation in which the auxiliary heat-dissipation member 133 and the heat dissipation member 110 are disposed at the same time, the auxiliary heat-dissipation member 133 and the heat dissipation member 110 may form a package, and the auxiliary heat-dissipation member 133, the heat dissipation member 110 and the heating component 120 may be packaged together to form a whole, thereby forming better protection for the heating component 120. Referring to FIG. 16, in an electronic assembly packaged by using, for example, a molding method, the auxiliary heat-dissipation member 133 may be in direct contact with the heating component 120, and the auxiliary heat-dissipation member may be, but is not limited to, epoxy resin molding compound or the like. Or, referring to FIG. 17, when the auxiliary heat-dissipation member 133 and the heat dissipation member 110 are made of metal materials, there is a spacing between the auxiliary heat-dissipation member 133 and the heating component 120 due to machining tolerance to ensure installation matching. Because the thermal conductivity of the auxiliary heat-dissipation member 133 and the heat dissipation member 110 is relatively high, this packaging form has lower thermal resistance, and may perform more efficient heat conduction.

Exemplarily, referring to FIG. 16, the auxiliary heat-dissipation member 133 may completely surround the heating component 120, and the auxiliary heat-dissipation member 133 may be in direct contact with the heating component 120. For example, a material of the auxiliary heat-dissipation member 133 is an insulating material, and the auxiliary heat-dissipation member 133 may not only play an insulating role, but also have functions of heat transfer, moisture and dust proof, and protection of the heating component 120.

Exemplarily, referring to FIG. 17, the auxiliary heat-dissipation member 133 may completely surround the heating component 120, there is a gap between the auxiliary heat-dissipation member 133 and the heating component 120, a thermal interface material is disposed in the gap, and the heating component 120 is connected with the auxiliary heat-dissipation member 133 through the thermal interface material. For example, the auxiliary heat-dissipation member 133 may be made of metal material, and the auxiliary heat-dissipation member 133 may not only have a strong heat transfer function, but also have functions of moisture-proof, dust-proof, and electrical protection for the heating component 120.

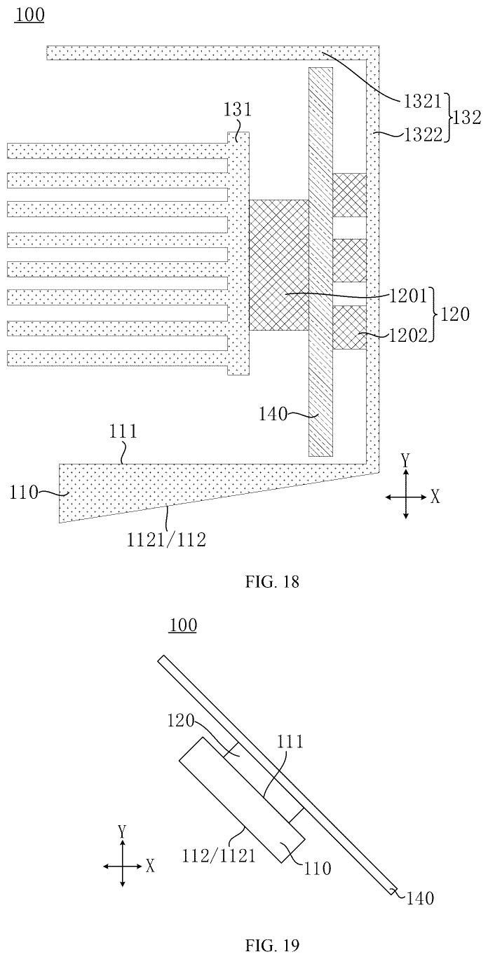

In some embodiments, referring to FIG. 18, the electronic assembly 100 may include a first auxiliary heat-dissipation member 131, a second auxiliary heat-dissipation member 132, a circuit board 140, and a heating component 120 which may include a first heating component 1201 and a second heating component 1202. Thickness direction of the circuit board 140 may be parallel to a horizontal direction X. The circuit board 140 is disposed at a side of a first surface 111 of a heat dissipation member 110, and the first heating component 1201 and the second heating component 1202 are respectively located at two sides of the circuit board 140 in the thickness direction. For example, the electronic assembly 100 may be an electronic device including a power supply and a load, where the electronic assembly 100 may be applied to a horizontal system. The control process and logic design of a cooling system are simpler, the design solution is mature, and the overall manufacturing and control costs of the system are lower. The first auxiliary heat-dissipation member 131 may be located at a side of the first heating component 1201 facing away from the circuit board 140, and heat of the first heating component 1201 may be transferred to the first auxiliary heat-dissipation member 131. The second auxiliary heat-dissipation member 132 may include a first extension portion 1321 and a second extension portion 1322 which are connected with each other. The first extension portion 1321, that is, a part of the second auxiliary heat-dissipation member 132, is located at a side of the circuit board 140 facing away from the heat dissipation member 110, and the second extension portion 1322, that is, the other part of the second auxiliary heat-dissipation member 132, is located at a side of the second heating component 1202 facing away from the circuit board 140. One end of the second extension portion 1322 is connected with the heat dissipation member 110, and the other end of the second extension portion 1322 is connected with the first extension portion 1321. Heat of the second heating component 1202 may be transferred to the second extension portion 1322 and then to the heat dissipation member 110 and the first extension portion 1321, respectively. In this way, by disposing the first auxiliary heat-dissipation member 131 at a bottom of the electronic assembly adopting phase-change liquid cooling, that is, in a direction in which the first heating component faces away from the circuit board, and by disposing the second auxiliary heat-dissipation member 132, heat dissipation area of the heat dissipation member 110 may be increased, which helps to improve the heat dissipation efficiency. In addition, the first auxiliary heat-dissipation member 131, the heat dissipation member 110 and the second auxiliary heat-dissipation member 132 form a better enclosing effect for the heating component 120, and may dissipate heat for the heating component 120 in various directions.

The following describes a device provided by an embodiment of the present application.

The embodiment of the present application provides a device. The device may include a phase-change cooling assembly and the electronic assembly 100 in the foregoing embodiments. The phase-change cooling assembly is configured for cooling and dissipating heat of the electronic assembly 100. The phase-change cooling assembly may include a housing and phase-change cooling liquid, where the housing has an accommodating cavity, the phase-change cooling liquid is located in the accommodating cavity, and at least a part of the second surface 112 of the heat dissipation member 110 of the electronic assembly 100 is immersed in the phase-change cooling liquid. In practical application scenarios, the electronic assembly 100 may be disposed in the phase-change cooling assembly, for example, along the gravity direction or obliquely. Exemplarily, referring to FIG. 19, by obliquely disposing the circuit board 140, the first surface 111 is intersected with the horizontal direction X. Exemplarily, in an implementation in which the first surface 111 is intersected with the horizontal direction X and the second surface 112 includes an inclined plane 1121, the first surface 111 and the second surface 112 may be parallel to each other, thereby reducing difficulty in manufacturing the heat dissipation member 110. When the second surface includes two adjacent inclined planes, or includes an inclined plane and an adjacent auxiliary plane, the two adjacent planes form an included angle, and the included angle may be concave inward or convex outward, that is, the included angle may be an acute angle, a right angle or an obtuse angle.

By setting the extending direction of the at least a part of the second surface 112, which is immersed in the phase-change cooling liquid, to be different from the horizontal direction X, a hindrance of a large bubble in heat exchange between the second surface 112 and the liquid working medium may be alleviated, thereby improving the boiling-and-heat-transfer coefficient, and improving the heat dissipation effect of the phase-change cooling liquid on the heat dissipation member 110, the heating component 120 and the electronic assembly 100, so that the heat dissipation effect of the device is better. The principle has been described, and is not described again.

Exemplarily, the phase-change cooling assembly may further include a condensing member, where the condensing member is disposed above the cooling liquid. There may be a spacing between the condensing member and the phase-change cooling liquid. The phase-change cooling liquid boils and generates vapor to take away the heat of the electronic assembly 100. After the rising vapor adheres to the condensing member and is cooled, it is liquefied to form small droplets and drops down. In this way, the circulation is repeated to achieve cooling of the electronic assembly 100, and to achieve the recycling of the phase-change cooling liquid.

Exemplarily, a boiling point of the phase-change cooling liquid may be greater than or equal to 40° C. and less than or equal to 70° C., which may avoid that the boiling point of the phase-change cooling liquid is too low so that the phase-change cooling liquid boils prematurely at room temperature with difficultly maintaining the liquid state, and avoid the influence on the cooling effect of the phase-change cooling liquid. In addition, it may also avoid that the boiling point of the phase-change cooling liquid is too high, and avoid the influence on the heat dissipation reliability of the electronic assembly 100 due to that the cooling liquid cannot produce the phase change when the heating component works. For example, the boiling point of the phase-change cooling liquid may be 40° C., 45° C., 50° C., 55° C., 60° C., 70° C., or any value between 40° C. and 70° C.

Exemplarily, the phase-change cooling liquid may be dielectric insulation liquid, thereby ensuring the insulation between the phase-change cooling liquid and the electronic assembly 100. The heat transfer capability of the phase-change cooling liquid may be strong, and it is non-flammable without flash point. For example, the phase-change cooling liquid may include fluorocarbon compounds.

Exemplarily, the device may be applied to a data center, which may be a horizontal system (FIG. 18) or a vertical system. For example, in the horizontal system, a server is vertically inserted into a rail from top to bottom and is immersed in the phase-change cooling liquid, mainly heating surfaces of a power supply module and a load are vertically disposed, and heat dissipation fins which are vertically arranged may also be added. In this way, continuously generated bubbles separate from the heating surfaces and continuously rise, and are not easily combined to a large sheet-like liquid film.

It should be noted that, in a case that the second surface 112 is a curved surface involved in the embodiment of the present application, the second surface 112 may be a concave curved surface, and may also be a convex curved surface, both of which have a function of enabling the bubble to separate. The accompanying drawings are merely taken as examples, including but not limited to this.

It should be noted that the values and the value ranges involved in the embodiment of the present application are approximate values, and there may be a certain range of errors due to the influence of the manufacturing process. These errors may be ignored by those skilled in the art.

Finally, it should be noted that, the foregoing embodiments are merely intended for illustrating the technical solutions of the present application, but not intended to limit it. Although the present application is described in detail with reference to the foregoing embodiments, it should be understood by those skilled in the art that, the technical solutions described in the foregoing embodiments may still be modified, or a part of or all technical features thereof may be replaced by equivalents. However, these modifications or replacements do not make the essence of the corresponding technical solutions depart from the scope of the technical solutions of the embodiments of the present application.

What is claimed is:

1. A heat dissipation member, configured for a heating component, comprising a first surface and a second surface which are oppositely disposed along a gravity direction, wherein the first surface is located above the second surface;
an extending direction of at least a part of the second surface is different from a horizontal direction;
the first surface is located below the heating component, and the at least a part of the second surface is disposed to be immersed in phase-change cooling liquid.

2. The heat dissipation member according to claim 1, wherein the second surface comprises at least one of an inclined plane which is obliquely intersected with the first surface and a curved surface, the inclined plane or the curved surface forms a first projection on the first surface along a direction perpendicular to the first surface, and a length between two points in the first projection is greater than or equal to 0.3 mm.

3. The heat dissipation member according to claim 2, wherein the second surface further comprises a plane parallel to the first surface.

4. The heat dissipation member according to claim 2, wherein the second surface further comprises the inclined plane, and an included angle between the inclined plane and the horizontal direction is greater than or equal to 10 degrees.

5. The heat dissipation member according to claim 2, wherein the second surface comprises the curved surface, and curvature of the curved surface is greater than or equal to 0.00264.

6. The heat dissipation member according to claim 1, wherein the first surface is parallel to the horizontal direction, and flatness of the first surface is less than or equal to 0.1 mm.

7. The heat dissipation member according to claim 1, wherein roughness of the second surface is greater than or equal to 0.01 mm and less than or equal to 0.3 mm.

8. The heat dissipation member according to claim 1, wherein thermal conductivity of the heat dissipation member is greater than or equal to 20 W/(m*k).

9. The heat dissipation member according to claim 2, wherein the second surface comprises a plurality of sub-surfaces, each of the plurality of sub-surfaces is in form of inclined plane or the curved surface, and extending directions of two adjacent sub-surfaces are different.

10. A heating component, wherein the heating component generates heat during an operation, and comprises: a first surface and a second surface which are oppositely disposed along a gravity direction, wherein the first surface is located above the second surface;
at least a part of the second surface is an inclined plane which is obliquely intersected with a horizontal direction and/or a curved surface, and at least a part of the second surface is configured to be disposed and immersed in phase-change cooling liquid.

11. An electronic assembly, comprising: the heat dissipation member according to claim 1 and a heating component, wherein the heating component generates heat during an operation;
the heating component is located on the first surface of the heat dissipation member.

12. The electronic assembly according to claim 11, wherein a surface of the heating component, which is away from the first surface, is adjacent to a surface of a circuit board, and a thickness direction of the circuit board is parallel to a gravity direction.

13. The electronic assembly according to claim 12, further comprising an auxiliary heat-dissipation member, wherein the auxiliary heat-dissipation member is located between the first surface and the circuit board, and is annularly disposed around periphery of the heating component;
the auxiliary heat-dissipation member is in contact with the heating component, or there is a spacing between the auxiliary heat-dissipation member and the heating component.

14. The electronic assembly according to claim 11, wherein the heating component is an electronic component or a power supply module.

15. The electronic assembly according to claim 13, wherein the auxiliary heat-dissipation member, the heat dissipation member and the heating component are packaged in whole body.

16. The electronic assembly according to claim 11, further comprising a first auxiliary heat-dissipation member, a second auxiliary heat-dissipation member and a circuit board, wherein the heating component comprises a first heating component and a second heating component, a thickness direction of the circuit board is parallel to a horizontal direction, and the first heating component and the second heating component are respectively located at two sides of the circuit board in the thickness direction;
the first auxiliary heat-dissipation member is located at a side of the first heating component facing away from the circuit board, a part of the second auxiliary heat-dissipation member is located at a side of the circuit board facing away from the heat dissipation member, and the other part of the second auxiliary heat-dissipation member is located at a side of the second heating component facing away from the circuit board and is in contact with the heat dissipation member.

17. A device, comprising: a phase-change cooling assembly and the electronic assembly according to claim 11, wherein the phase-change cooling assembly comprises a housing and phase-change cooling liquid, the housing has an accommodating cavity, the phase-change cooling liquid is located in the accommodating cavity, and at least a part of the second surface of the heat dissipation member of the electronic assembly is immersed in the phase-change cooling liquid.

18. The device according to claim 17, wherein a boiling point of the phase-change cooling liquid is greater than or equal to 40° C. and less than or equal to 70° C.

19. The device according to claim 17, wherein the phase-change cooling liquid is dielectric insulation liquid.

20. The device according to claim 17, wherein a surface of the heating component, which is away from the first surface, is adjacent to a surface of a circuit board, and a thickness direction of the circuit board is parallel to a gravity direction.

21. The device according to claim 17, wherein the electronic assembly further comprises a first auxiliary heat-dissipation member, a second auxiliary heat-dissipation member and a circuit board, wherein the heating component comprises a first heating component and a second heating component, a thickness direction of the circuit board is parallel to a horizontal direction, and the first heating component and the second heating component are respectively located at two sides of the circuit board in the thickness direction;
the first auxiliary heat-dissipation member is located at a side of the first heating component facing away from the circuit board, a part of the second auxiliary heat-dissipation member is located at a side of the circuit board facing away from the heat dissipation member, and the other part of the second auxiliary heat-dissipation member is located at a side of the second heating component facing away from the circuit board and is in contact with the heat dissipation member.
